(19) United States
(12) Patent Application Publication
(10) Pub. No.: US 2024/0038949 A1
(43) Pub. Date: Feb. 1, 2024

(54) LIGHT-EMITTING PACKAGE AND FORMING METHOD THEREOF

(71) Applicant: TAIWAN SEMICONDUCTOR MANUFACTURING COMPANY LTD., HSINCHU (TW)

(72) Inventors: JHENG-HONG JIANG, HSINCHU (TW); SHING-HUANG WU, HSINCHU (TW); CHIA-WEI LIU, HSINCHU COUNTY (TW)

(21) Appl. No.: 17/816,208

(22) Filed: Jul. 29, 2022

(51) Int. Cl. H01L 33/62; H01L 33/00; H01L 33/64

(52) U.S. Cl. CPC H01L 33/62; H01L 33/005; H01L 33/645; H01L 2933/0066

(57) ABSTRACT

A light-emitting package and a method for forming a light-emitting package are provided. The light-emitting package includes a substrate, an interconnection structure and a thermoelectric element. The interconnection structure is disposed over the substrate. The interconnection structure comprises a light-emitting element. The thermoelectric element penetrates through the substrate, extends into the interconnection structure and stops at the light-emitting element. The thermoelectric element is configured for local cooling of the light-emitting element.

### BACKGROUND

The semiconductor industry has experienced rapid growth and demands for highly integrated semiconductor devices are increasing. Technological advances in design and materials have created integrated circuit (IC) generations that are smaller and more complex than each previous generation. Integration of an IC structure with other electrical components in order to perform a specific function is becoming increasingly challenging due to the trend toward complex and reduced-scale IC structures. The integration of the IC structure and an electrical component is required not only to enhance performance of the device but also to provide good compatibility of the IC structure and the electrical component.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a cross-sectional view of a light-emitting package according to aspects of one or more embodiments of the present disclosure.

FIG. 2 is a top view of a light-emitting pixel according to aspects of one or more embodiments of the present disclosure.

FIG. 3 is a top view of a luminous pixel array according to aspects of one or more embodiments of the present disclosure.

FIG. 4 is a top view of a luminous pixel array according to aspects of one or more embodiments of the present disclosure.

FIGS. 5A, 5B, 5C and 5D are bottom views of luminous pixel arrays according to aspects of one or more embodiments of the present disclosure.

FIG. 6 is a cross-sectional view of a light-emitting package according to aspects of one or more embodiments of the present disclosure.

FIG. 7 is a cross-sectional view of a light-emitting package according to aspects of one or more embodiments of the present disclosure.

FIG. 8 is a cross-sectional view of a light-emitting package according to aspects of one or more embodiments of the present disclosure.

FIG. 9 is a flowchart representing a method for forming a light-emitting package according to aspects of one or more embodiments of the present disclosure.

FIGS. 10 to 19 are schematic drawings illustrating a method for forming a light-emitting package at various fabrication stages constructed according to aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

A light-emitting diode (LED) is a semiconductor light source for generating a light at a specified wavelength or in a range of wavelengths. An LED emits light when a voltage is applied across a p-n junction formed by oppositely doped semiconductor compound layers. Different wavelengths of light can be generated using different materials by varying the bandgaps of the semiconductor layers and by fabricating an active layer within the p-n junction. An LED packaging involves integrating the LED over a package substrate and forming electrical connections to power and control the LED. While existing methods of packaging an LED have been generally adequate for their intended purposes, they have not been entirely satisfactory in every aspect. A challenge with the LED package is heat dissipation. As electricity flows to the LED, it generates heat in the package. Effective heat dissipation in the package is essential to preventing premature failure of or damage to nearby components.

Various embodiments of the present disclosure provide a light-emitting package as well as a method for forming the light-emitting package that provides one or more improvements over existing approaches. Some embodiments of the present disclosure are directed toward a light-emitting package comprising a thermoelectric element, as well as a method for forming the light-emitting package. According to some embodiments, the light-emitting package comprises a substrate, a light-emitting element over the substrate, and one or more thermoelectric elements electrically coupled to the light-emitting element. The thermoelectric element may be configured for local cooling of the light-emitting element. The thermoelectric element may transfer the heat generated by the light-emitting element to a back surface of the substrate, and hence reduce a temperature of the light-emitting package. Accordingly, damage to nearby components may be reduced. Moreover, a better performance of the light-emitting package may be achieved.

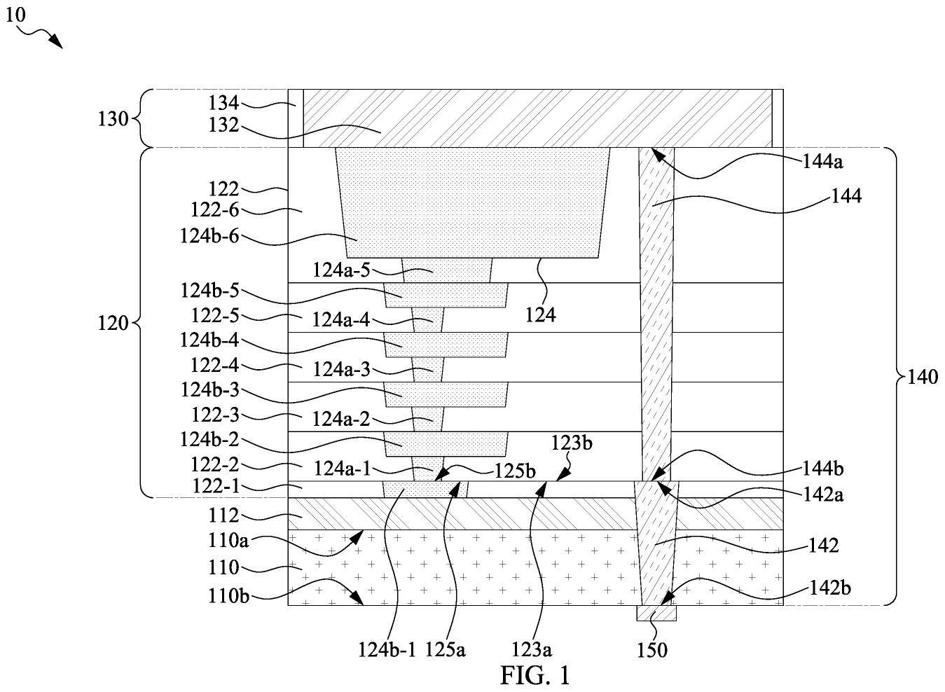

FIG. 1 is a cross-sectional view of a light-emitting package 10 according to aspects of one or more embodiments of the present disclosure. Referring to FIG. 1, the light-emitting package 10 includes a substrate 110 and an interconnection structure 120 over the substrate 110. The light-emitting package 10 may further include a light-emitting structure 130 over the interconnection structure 120. The light-emitting structure 130 includes one or more light-emitting elements 132. Alternatively, the light-emitting structure 130 and the interconnection structure 120 are together referred to as an interconnection feature (or structure) of the light-emitting package 10, hence the light-emitting element 132 may be considered as an element of the interconnection feature of the light-emitting package 10. The light-emitting package 10 may further include one or more thermoelectric elements 140. The thermoelectric element 140 may penetrate through the substrate 110, extend into the interconnection structure 120 and stop at the light-emitting element 132. As will be described in more detail below, the thermoelectric element 140 may be configured for local cooling of the light-emitting element 132. In some embodiments, the light-emitting package 10 is referred to as an integrated circuit (IC) device that includes the light-emitting element 132. According to various aspects of the present disclosure, FIG. 1 may be a fragmentary diagrammatic view of part or all of the light-emitting package 10. FIG. 1 has been simplified for the sake of clarity to better understand the inventive concepts of the present disclosure. Additional features may be added to the light-emitting package 10, and some of the features described below may be replaced, modified, or eliminated in other embodiments of the light-emitting package 10.

In some embodiments, the substrate 110 is a semiconductor substrate that includes silicon. Alternatively or additionally, the substrate 110 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlinAs, AlGaAs, GalnAs, GaInP, and/or GaInAsP; or a combination thereof. Alternatively, the substrate 110 is a semiconductor-on-insulator substrate, such as a silicon-on-insulator (SOI) substrate, a silicon germanium-on-insulator (SGOI) substrate, or a germanium-on-insulator (GOI) substrate. The substrate 110 may include various doped regions (not shown) depending on design requirements of the light-emitting package 10. In some implementations, the substrate 110 includes p-type doped regions (for example, p-type wells) doped with p-type dopants, such as boron, indium, other p-type dopants, or combinations thereof. In some implementations, the substrate 110 includes n-type doped regions (for example, n-type wells) doped with n-type dopants, such as phosphorus, arsenic, other n-type dopants, or combinations thereof. In some implementations, the substrate 110 includes doped regions formed with a combination of p-type dopants and n-type dopants. The various doped regions may be formed directly on and/or in the substrate 110, for example, providing a p-well structure, an n-well structure, a dual-well structure, a raised structure, or a combination thereof. An ion implantation process, a diffusion process, and/or another suitable doping process can be performed to form the various doped regions.

In some embodiments, a device layer 112 is disposed between the interconnection structure 120 and the substrate 110. The substrate 110 includes a front surface 110a and a back surface 110b. The device layer 112 is disposed over the front surface 110a of the substrate 110. The device layer 112 may include one or more IC features fabricated by a front-end-of-line (FEOL) operation (sometimes referred to as FEOL features or structures). FEOL operation encompasses processes related to fabricating IC devices, such as transistors. For example, FEOL processes may include forming isolation features, gate structures, and source and drain features (generally referred to as source/drain features). In some implementations, the device layer 112 includes various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. The transistors may be planar transistors or multi-gate transistors, such as fin-like FETs (FinFETs). The illustrated device layer 112 has been simplified for the sake of clarity to provide better understanding of the inventive concepts of the present disclosure. Additional features, such as isolation features, gate structures, and source/drain features, may be added to the device layer 112. In some embodiments, a total thickness of the device layer 112 and the substrate 110 is substantially in a range between about 0.01 μm and about 1000 μm.

In some embodiments, the interconnection structure 120 is disposed over the front surface 110a of the substrate 110. The interconnection structure 120 may also be referred to as a multilayer interconnect (MLI) feature. The interconnection structure 120 electrically connects various devices (for example, the light-emitting element 132, the thermoelectric element 140, transistors, resistors, capacitors, and/or inductors) and/or components (for example, gate structures and/or source/drain features) of the light-emitting package 10, such that the various devices and/or components can operate as specified by design requirements of the light-emitting package 10. The interconnection structure 120 may include one or more interconnect features fabricated by a back-end-of-line (BEOL) operation (sometimes referred to as BEOL features or structures). BEOL operation encompasses processes related to fabricating interconnect features (or structures) that interconnect IC features fabricated by FEOL process, thereby enabling operation of the IC devices. For example, BEOL processes may include forming multilayer interconnect features that facilitate operation of the IC devices.

The interconnection structure 120 includes a combination of dielectric layers 122 and conductive layers 124 configured to form various interconnect features. The conductive layers 124 are configured to form vertical interconnect features, such as conductive vias 124a, and/or horizontal interconnect features, such as conductive lines 124b. Vertical interconnect features connect horizontal interconnect features in different dielectric layers 122 (or different planes) of the interconnection structure 120. In some implementations, vertical interconnect features and horizontal interconnect features have respective lengths and widths measured along the same direction, where vertical interconnect features have lengths greater than their widths, and horizontal interconnect features have lengths smaller than their widths. During operation of the light-emitting package 10, the interconnect features are configured to route signals between the devices and/or the components of the light-emitting package 10 and/or distribute signals (for example, voltage signals and/or ground signals) to the devices and/or the components of the light-emitting package 10. It should be noted that, although the interconnection structure 120 is depicted with a given number of dielectric layers 122 and conductive layers 124, the present disclosure includes embodiments in which the interconnection structure 120 has more or fewer dielectric layers 122 and/or conductive layers 124 depending on design requirements of the light-emitting package 10. In some embodiments, a thickness of the interconnection structure 120 is substantially in a range between about 100 Å and about 100 kÅ.

The dielectric layers 122, such as inter-metal dielectric (IMD) layers (or inter-layer dielectric (ILD) layers) 122-1, 122-2, 122-3, 122-4, 122-5 and 122-6, are disposed over the substrate 110. The IMD layers 122-1 to 122-6 include a dielectric material including, for example, silicon oxide, silicon nitride, silicon oxynitride, USG, PSG, BD, low-k dielectric material, extreme low-k dielectric material, other suitable dielectric material, or combinations thereof. In the depicted embodiment, the IMD layers 122-1 to 122-6 are dielectric layers that include a low-k dielectric material (generally referred to as low-k dielectric layers). The IMD layers 122-1 to 122-6 may include a multilayer structure having multiple dielectric materials. Alternatively or additionally, the interconnection structure 120 may further include one or more contact etch stop layers (CESL) disposed over the substrate 110, for example, a CESL disposed between the IMD layer 122-1 and the IMD layer 122-2. In some implementations, a CESL is also disposed between the substrate 110 and the IMD layer 122-1. The CESLs may include a material different from materials of the IMD layers 122-1 to 122-6, such as a dielectric material that is different from the dielectric material of the IMD layers 122-1 to 122-6. For example, where the IMD layers 122-1 to 122-6 include a low-k dielectric material, the CESLs include silicon and nitrogen (for example, silicon nitride or silicon oxynitride).

The conductive layers 124 (sometimes referred to as BEOL conductive features), such as conductive vias 124a-1, 124a-2, 124a-3, 124a-4 and 124a-5 and conductive lines (sometimes referred to as metallization layers) 124b-1, 124b-2, 124b-3, 124b-4, 124b-5 and 124b-6, are disposed in the IMD layers 122-1 to 122-6 to form interconnect features. The conductive vias 124a-1 to 124a-5 electrically couple and/or physically couple conductive lines 124b-1 to 124b-6 in different IMD layers of the interconnection structure 120 to one another. For example, the conductive via 124a-1 is disposed on the conductive line 124b-1, such that the conductive via 124a-1 connects the conductive line 124b-1 in the IMD layer 122-1 to the conductive line 124b-2 in the IMD layer 122-2. The BEOL conductive features, such as the conductive vias 124a-1 to 124a-5 and the conductive lines 124b-1 to 124b-6, include any suitable conductive material, such as Ta, Ti, Al, Cu, Co, W, tantalum nitride (TaN), titanium nitride (TiN), and/or other suitable conductive materials. Alternatively or additionally, the BEOL conductive features include an alloy or a composite material, such as silicon, AlCu, AlSiCu, and/or other suitable conductive materials.

The light-emitting structure 130 is disposed over the interconnection structure 120. The light-emitting structure 130 includes one or more light-emitting elements 132 disposed in one or more dielectric layers 134. The light-emitting element 132 includes a light-emitting diode (LED), a mini LED, a micro LED, a quantum dot, an organic LED (OLED), other suitable light-emitting elements, or a combination thereof. The dielectric layer 134 include a dielectric material including silicon oxide, silicon nitride, silicon oxynitride, USG, PSG, BD, low-k dielectric material, extreme low-k dielectric material, other suitable dielectric material, or a combination thereof. The dielectric layer 134 and the dielectric layers 122 may include same or different dielectric materials. The light-emitting element 132 is electrically connected to the conductive line 124b-6. In some embodiments, the BEOL conductive features (i.e., the conductive vias 124a-1 to 124a-5 and the conductive lines 124b-1 to 124b-6) electrically couple and/or physically couple the light-emitting element 132 to the FEOL features in the device layer 112. The BEOL conductive features may route signals between the light-emitting element 132 and the FEOL features in the device layer 112. In some embodiments, a thickness of the light-emitting element 132 is substantially in a range between about 20 Å and about 50 kÅ.

In some embodiments, a conductive pad (sometimes referred to as a bonding pad) 150 underlies the back surface 110b of the substrate 110. The conductive pad 150 is electrically connected to the thermoelectric element 140. The conductive pad 150 may be configured to receive an input voltage. The conductive pad 150 includes any suitable conductive material, such as Ta, Ti, Al, Cu, Co, W, tantalum nitride (TaN), titanium nitride (TiN), and/or other suitable conductive materials. Alternatively or additionally, the conductive pad 150 includes an alloy or a composite material, such as such as silicon, AlCu, AlSiCu, and/or other suitable conductive materials. The conductive pad 150 and the BEOL conductive features may include same or different dielectric materials.

The thermoelectric element 140 is disposed within the substrate 110, the device layer 112 and the interconnection structure 120. The thermoelectric element 140 penetrates through the substrate 110 and is exposed through both the back surface 110b and the front surface 110a of the substrate 110. The thermoelectric element 140 may further extend into the interconnection structure 120 and may penetrate through the interconnection structure 120. The thermoelectric element 140 electrically couples and/or physically couples the light-emitting element 132 to the conductive pad 150. The thermoelectric element 140 (sometimes referred to as a doped semiconductor structure) includes a doped semiconductor material including, for example, doped polycrystalline silicon (also called polysilicon), doped polycrystalline silicon-germanium, and/or other suitable conductive materials. The thermoelectric element 140 may be doped with a p-type dopant, such as boron, indium, another p-type dopant, or a combination thereof. Alternatively, the thermoelectric element 140 may be doped with an n-type dopant, such as phosphorus, arsenic, another n-type dopant, or a combination thereof.

In some embodiments, the thermoelectric element 140 is tapered from the light-emitting element 132 toward the front surface 110a (or the back surface 110b) of the substrate 110. In some embodiments, the thermoelectric element 140 includes a first tapered portion 142 and a second tapered portion 144 coupled to the first tapered portion 142. The first tapered portion 142 is tapered from a surface 123a of the IMD layer 122-1 toward the back surface 110b of the substrate 110. The second tapered portion 144 is tapered from the light-emitting element 132 toward the front surface 110a of the substrate 110 or the surface 123b of the IMD layer 122-2. In some embodiments, a height of the second tapered portion 144 is greater than a height of the first tapered portion 142.

The first tapered portion 142 penetrates through the substrate 110. In some embodiments, the first tapered portion 142 further penetrates through the device layer 112. Alternatively or additionally, the first tapered portion 142 further penetrates through the IMD layer 122-1. The first tapered portion has a surface 142a and a surface 142b opposite to the surface 142a. In some embodiments, the surface 142a of the first tapered portion 142 is substantially level with a surface 125a of the conductive line 124b-1. Alternatively or additionally, the surface 142b of the first tapered portion 142 is substantially level with the back surface 110b of the substrate 110. The surface 142b of the first tapered portion 142 electrically connects to and/or physically connects to the conductive pad 150. In some embodiments, a width of the surface 142a is greater than a width of the surface 142b.

The second tapered portion 144 penetrates through a portion of the interconnection structure 120. In some embodiments, the second tapered portion 144 penetrates through the IMD layers 122-2 to 122-6. The second tapered portion has a surface 144a and a surface 144b opposite to the surface 144a. In some embodiments, the surface 144a of the second tapered portion 144 is substantially level with a surface of the conductive line 124b-6. The surface 144a of the second tapered portion 144 electrically connects to and/or physically connects to the light-emitting element 132. The surface 144a of the second tapered portion 144 contacts the light-emitting element 132. Alternatively or additionally, the surface 144b of the second tapered portion 144 is substantially level with a surface 125b of the conductive via 124a-1 or a surface 123b of the IMD layer 122-2. The surface 144b of the second tapered portion 144 electrically connects to and/or physically connects to the surface 142a of the first tapered portion 142. In some embodiments, a width of the surface 144a is greater than a width of the surface 144b. In some embodiments, the width of the surface 144a is substantially in a range between about 0.01 μm and about 80 μm.

The thermoelectric element 140 may be configured as a thermoelectric cooler (TEC) when the conductive pad 150 receives an input voltage. In some embodiments, the thermoelectric cooling is achieved by passing a DC electric current through the thermoelectric element 140. The thermoelectric element 140 is configured for local cooling of the light-emitting element as follows. In embodiments where the thermoelectric element 140 is doped with an n-type dopant, when a positive bias is applied to the conductive pad 150, the electric field forces electrons, the majority carrier of high concentration doped n-type polysilicon, to flow toward the back surface 110b of the substrate 110. As the electrons flow toward the back surface 110b of the substrate 110, the electrons also carry heat from the light-emitting element 132 over the front surface 110a of the substrate 110. In embodiments where the thermoelectric element 140 is doped with a p-type dopant, when a negative bias is applied to the conductive pad 150, the electric field forces electric holes, the majority carrier of high concentration doped p-type polysilicon, to flow toward the back surface 110b of the substrate 110. As the electric holes flow toward the back surface 110b of the substrate 110, the electric holes also carry heat from the light-emitting element 132 over the front surface 110a of the substrate 110. Accordingly, the light-emitting element 132 may be cooled by the thermoelectric element 140.

The proposed light-emitting package 10 provides advantages. In some comparative embodiments where the thermoelectric element 140 is absent, the heat generated by the light-emitting element 132 may damage nearby components (e.g., the conductive line 124b-6, the conductive via 124a-5 and/or the IMD layer 122-6). Hence, premature failure of nearby components or damage to nearby components occurs due to the heat generated by the light-emitting element 132. The proposed light-emitting package 10 includes the thermoelectric element 140. The thermoelectric element 140 may transfer the heat generated by the light-emitting element 132 to the back surface 110b of the substrate 110, and hence reduce the temperature of the light-emitting package 10. Accordingly, the damage to the nearby components may be reduced. Moreover, a better performance of the light-emitting package 10 may be achieved.

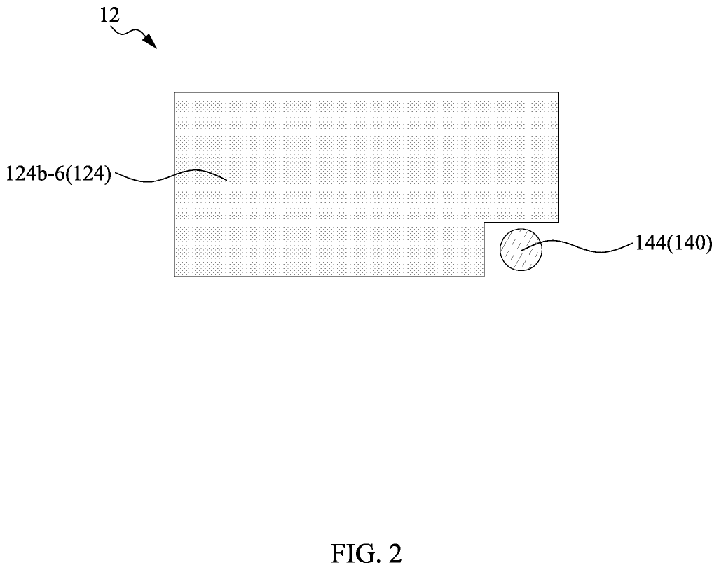

FIG. 2 is a top view of a light-emitting pixel 12 according to aspects of one or more embodiments of the present disclosure. FIG. 2 may be a fragmentary diagrammatic view of the light-emitting pixel 12. FIG. 2 illustrates a top view of the conductive line 124b-6 (sometimes referred to as a topmost conductive line) and the thermoelectric element 140. As illustrated in FIG. 2, the thermoelectric element 140 may be arranged at a corner of the conductive line 124b-6. In some embodiments, the light-emitting package 10 including one light-emitting element 132 is configured as a light-emitting pixel 12 of a luminous pixel array. In other words, each light-emitting pixel 12 includes one light-emitting element 132 and one thermoelectric element 140, and the thermoelectric element 140 is arranged at a corner of the light-emitting pixel 12.

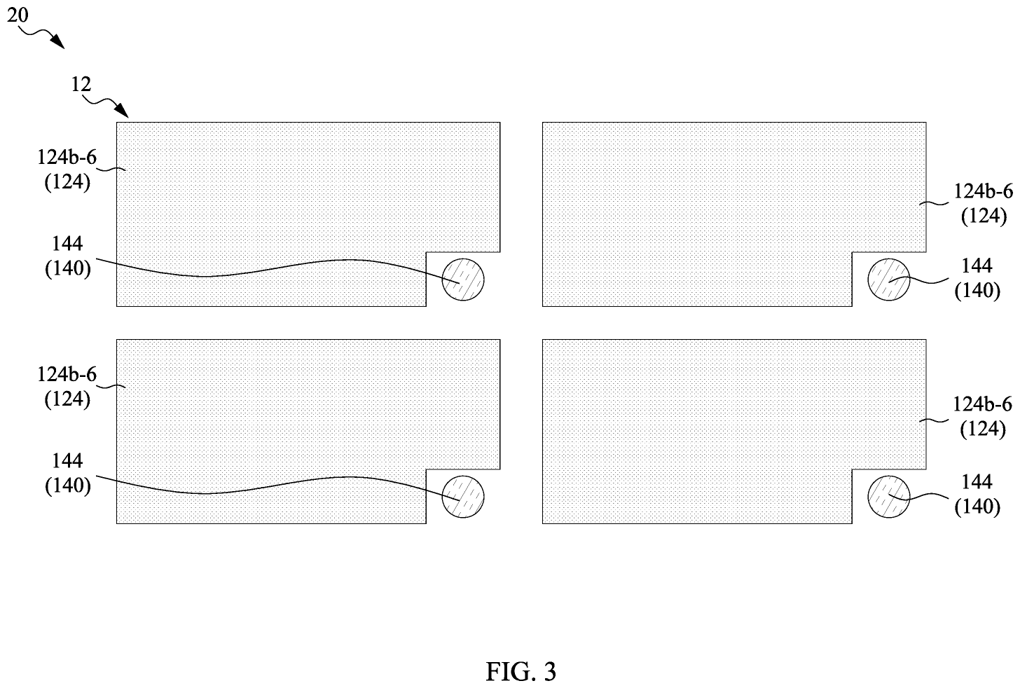

FIG. 3 is a top view of a luminous pixel array 20 according to aspects of one or more embodiments of the present disclosure. FIG. 3 may be a fragmentary diagrammatic view of part or all of the luminous pixel array 20. It should be noted that, although the luminous pixel array 20 is depicted with a given number of the light-emitting pixels 12, the present disclosure includes embodiments in which the luminous pixel array 20 has more or fewer light-emitting pixels 12 depending on design requirements of the luminous pixel array 20. As illustrated in FIG. 3, each of the thermoelectric elements 140 in different light-emitting pixels 12 may be arranged at a same respective corner of each of the light-emitting pixels 12. It should be noted that, although the top view of the thermoelectric element 140 is depicted as a circle, the thermoelectric element 140 may be implemented with different shapes, such as rectangle, triangle, square, polygon, or other suitable shapes.

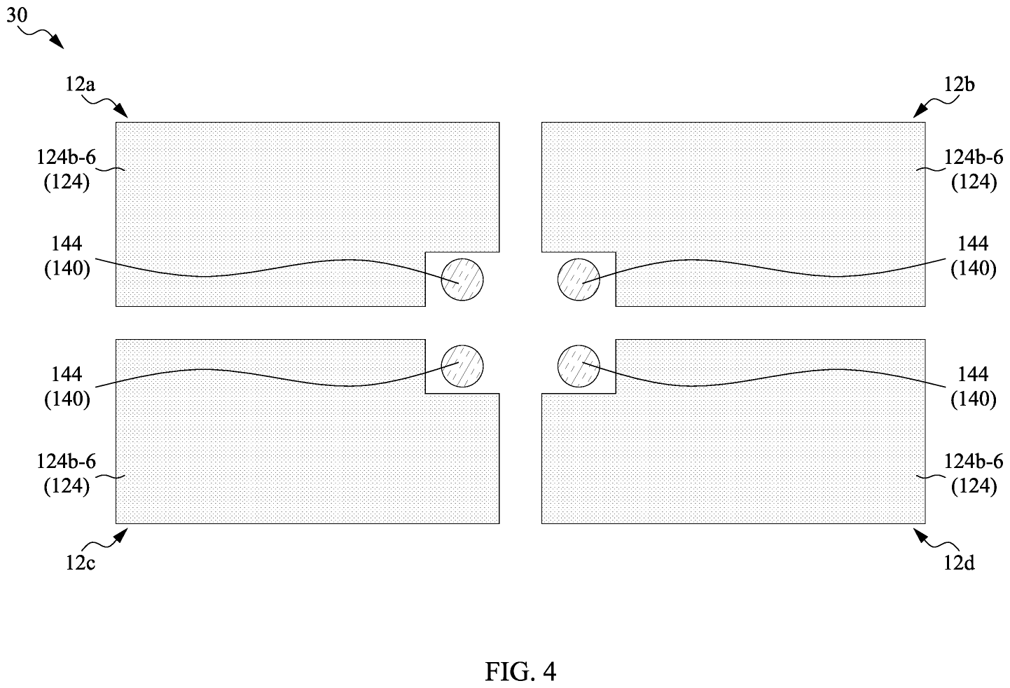

FIG. 4 is a top view of a luminous pixel array 30 according to aspects of one or more embodiments of the present disclosure. The luminous pixel array 30 in FIG. 4 is similar to the luminous pixel array 20 in FIG. 3, except that each of the thermoelectric elements 140 in different light-emitting pixels 12a, 12b, 12c and 12d are arranged adjacent to one another. For example, the thermoelectric element 140 in the light-emitting pixel 12a is arranged adjacent to the thermoelectric element 140 in the light-emitting pixel 12b and the thermoelectric element 140 in the light-emitting pixel 12c. Also, the thermoelectric element 140 in the light-emitting pixel 12d is arranged adjacent to the thermoelectric element 140 in the light-emitting pixel 12b and the thermoelectric element 140 in the light-emitting pixel 12c. In some embodiments, the light-emitting pixels 12a, 12b, 12c and 12d are configured to generate different wavelengths of light.

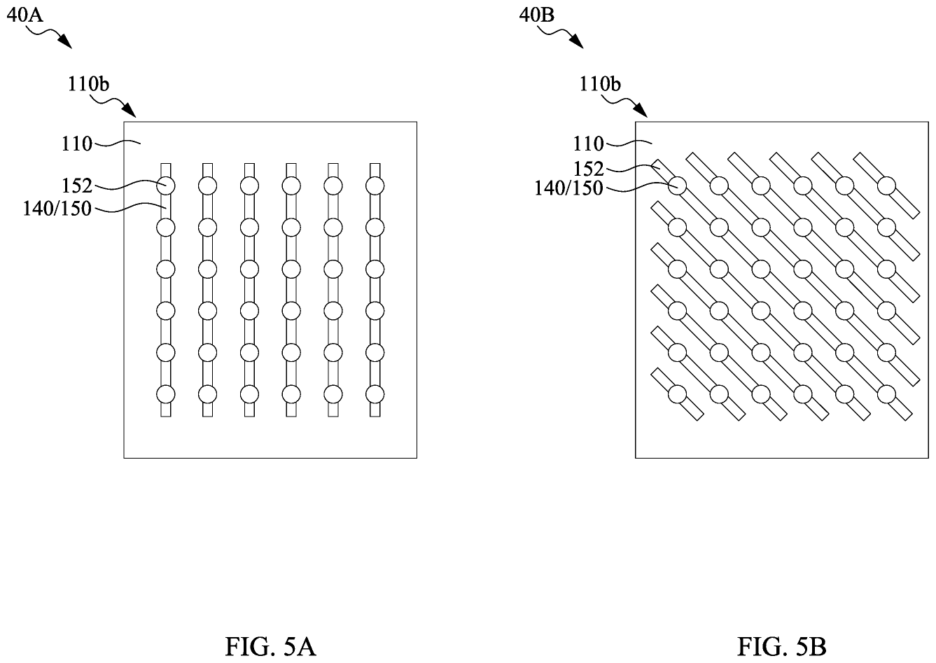

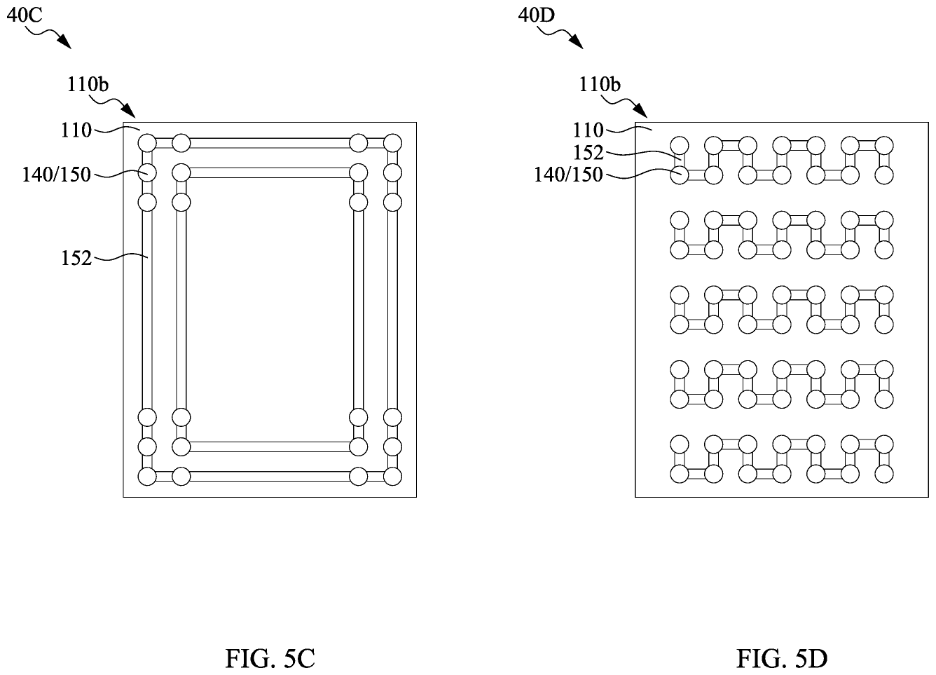

FIGS. 5A, 5B, 5C and 5D are bottom views of luminous pixel arrays 40A, 40B, 40C and 40D, respectively, according to aspects of one or more embodiments of the present disclosure. FIGS. 5A to 5D may be fragmentary diagrammatic views of the luminous pixel array 40A, 40B, 40C and 40D, in portion or entirety. FIGS. 5A to 5D illustrate bottom views of conductive pads 150 or the thermoelectric elements 140 as well as the back surface 110b of the substrate 110. FIGS. 5A to 5D further illustrate one or more connection lines 152 for connecting to the conductive pads 150 or the thermoelectric elements 140 in different light-emitting pixels (e.g., the light-emitting pixel 12). In some embodiments, a single connection line 152 is electrically connected to a single input voltage. In other words, the conductive pads 150 in a same connection line 152 may receive a same input voltage. Accordingly, the thermoelectric elements 140 in different light-emitting pixels electrically coupled to a same connection line 152 may be configured for local cooling of the light-emitting elements 132 in the respective light-emitting pixels.

The arrangement of the connection lines 152 may be altered depending on heat dissipation requirements of different regions. In some embodiments as shown in FIG. 5A, the connection line 152 is vertically connected to the conductive pads 150 or the thermoelectric elements 140 in different light-emitting pixels. In some embodiments as shown in FIG. 5B, the connection line 152 is diagonally connected to the conductive pads 150 or the thermoelectric elements 140 in different light-emitting pixels. In some embodiments as shown in FIG. 5C, the conductive pads 150 or the thermoelectric elements 140 in different belt regions are connected to a same connection line 152. In some embodiments as shown in FIG. 5D, the conductive pads 150 or the thermoelectric elements 140 in different rows (e.g., two rows) are connected to a same connection line 152.

The structures of the present disclosure are not limited to the above-mentioned embodiments and may have other different embodiments. To simplify the description and for convenience of comparison between each of the embodiments of the present disclosure, identical (or like) components in each of the following embodiments are marked with identical (or like) numerals. For making it easier to compare differences between the embodiments, the following description will detail dissimilarities among different embodiments, while description of identical features, values and definitions will not be repeated.

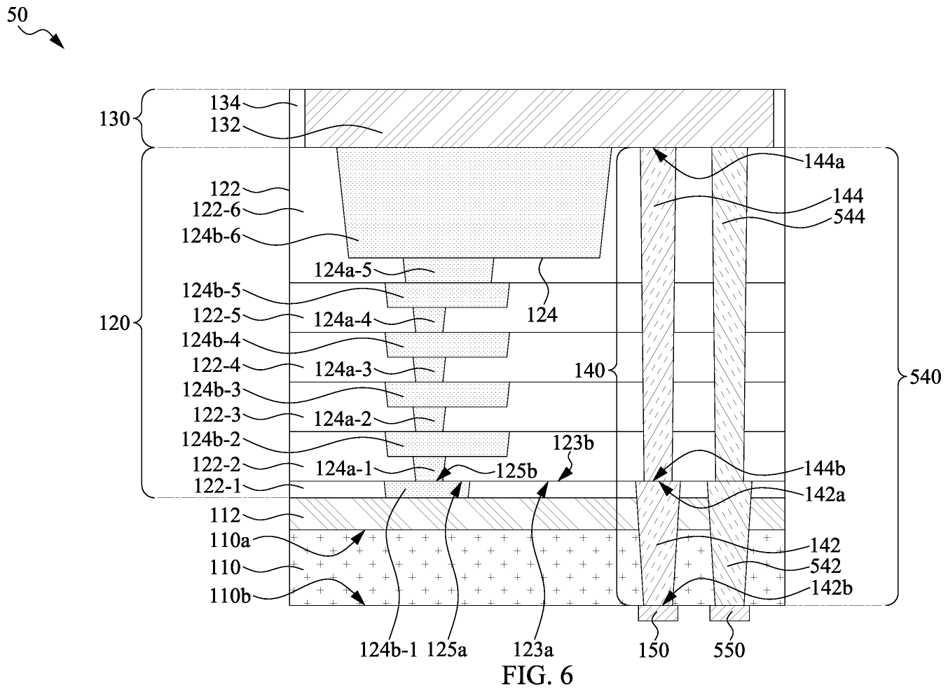

FIG. 6 is a cross-sectional view of a light-emitting package 50 according to aspects of one or more embodiments of the present disclosure. The light-emitting package 50 in FIG. 6 is similar to the light-emitting package 10 in FIG. 1, except that the light-emitting package 50 further includes a thermoelectric element 540 and a conductive pad 550. In some embodiments, the thermoelectric element 540 includes a first tapered portion 542 and a second tapered portion 544 coupled to the first tapered portion 542. In some embodiments, a height of the second tapered portion 544 is greater than a height of the first tapered portion 542. The thermoelectric element 540 electrically couples and/or physically couples the light-emitting element 132 to the conductive pad 550. In some embodiments, the thermoelectric element 140 is doped with a p-type dopant, while the thermoelectric element 540 is doped with an n-type dopant, or vice versa. In some implementations where the thermoelectric element 140 is doped with a p-type dopant and the thermoelectric element 540 is doped with an n-type dopant, the conductive pad 150 is configured to receive a negative input voltage and the conductive pad 550 is configured to receive a positive input voltage.

The thermoelectric element 540 and the thermoelectric element 140 together cool the light-emitting package 50 as follows. When a positive bias is applied to the conductive pad 550, the electric field forces electrons, the majority carrier of high concentration doped n-type polysilicon of the thermoelectric element 540, to flow toward the back surface 110b of the substrate 110. As the electrons flow toward the back surface 110b of the substrate 110, the electrons also carry heat from the light-emitting element 132 on the front surface 110a of the substrate 110. Also, because electric holes flow in an opposite direction to electrons in an electric field, in the high concentration doped p-type polysilicon of the thermoelectric element 140, the majority carrier electric holes also flow toward the back surface 110b of the substrate 110. Accordingly, the light-emitting element 132 may be cooled by the thermoelectric element 140 and the thermoelectric element 540.

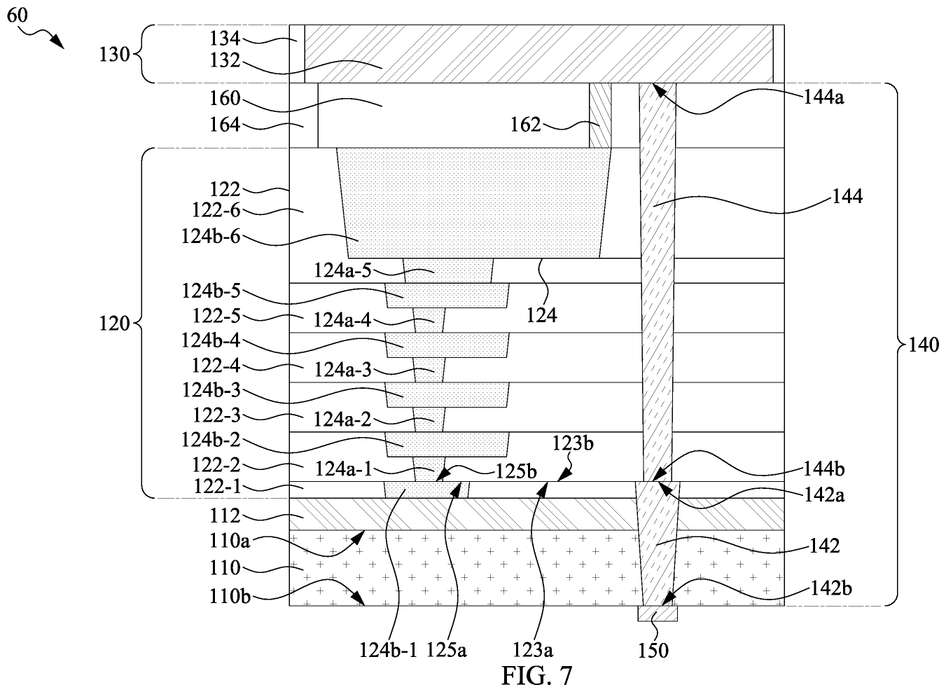

FIG. 7 is a cross-sectional view of a light-emitting package 60 according to aspects of one or more embodiments of the present disclosure. The light-emitting package 60 in FIG. 7 is similar to the light-emitting package 10 in FIG. 1, except that the light-emitting package 60 further includes an optical isolation 160 between the light-emitting element 132 and the conductive line 124b-6. The optical isolation 160 includes a dielectric material including, for example, silicon oxide, USG, other suitable dielectric material, or a combination thereof. In some embodiments, the optical isolation 160 may provide a suitable optical path difference for the light-emitting element 132. The light-emitting package 60 may further include a conductive via 162 adjacent to the optical isolation 160 and electrically connecting the conductive line 124b-6 to the light-emitting element 132. In some embodiments, a material of the conductive via 162 is substantially same as a material of the thermoelectric element 140. The optical isolation 160 and the conductive via 162 may be disposed in a dielectric layer 164. In some embodiments, a material of the dielectric layer 164 is substantially same as a material of the dielectric layer 122. In some embodiments as shown in FIG. 7, a width of the conductive via 162 is substantially uniform from the light-emitting element 132 toward the conductive line 124b-6. In some embodiments, the width of the conductive via 162 is substantially in a range between about 0.01 μm and about 10 μm. Alternatively, the conductive via 162 is tapered from the light-emitting element 132 toward the conductive line 124b-6. In some embodiments, a total thickness of the interconnection structure 120 and the optical isolation 160 is substantially in a range between about 100 Å and about 100 kÅ.

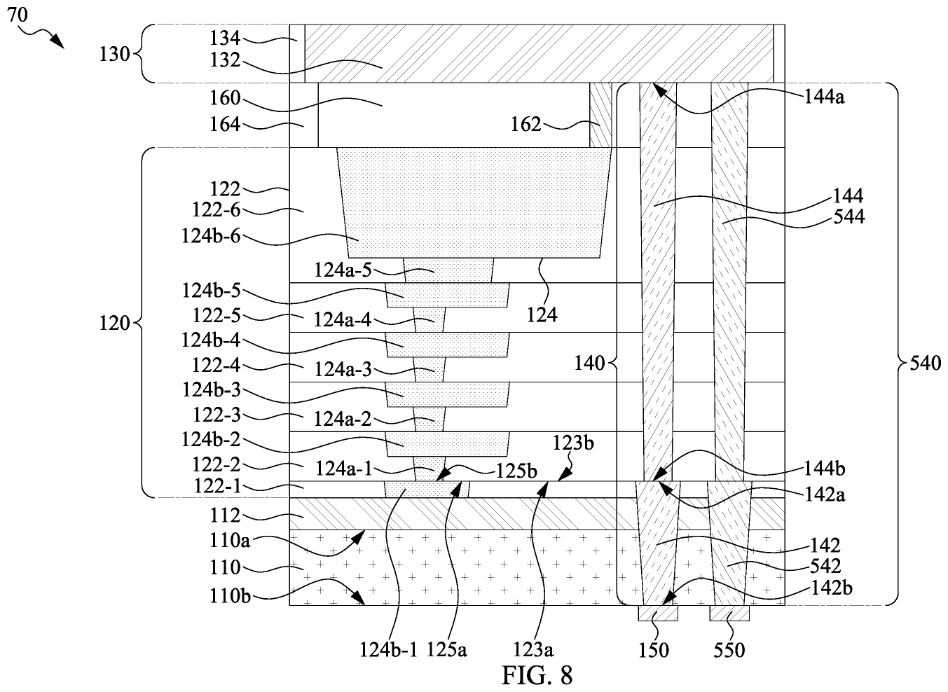

FIG. 8 is a cross-sectional view of a light-emitting package 70 according to aspects of one or more embodiments of the present disclosure. The light-emitting package 70 in FIG. 8 is similar to the light-emitting package 50 in FIG. 6, except that the light-emitting package 70 further includes an optical isolation 160 between the light-emitting element 132 and the conductive line 124b-6. Additionally, the light-emitting package 70 further includes a conductive via 162 adjacent to the optical isolation 160 and electrically connecting the conductive line 124b-6 to the light-emitting element 132. In some embodiments, a material of the conductive via 162 is substantially same as a material of the thermoelectric element 140. Alternatively, a material of the conductive via 162 is substantially same as a material of the thermoelectric element 540. In some embodiments as shown in FIG. 8, a width of the conductive via 162 is substantially uniform from the light-emitting element 132 toward the conductive line 124b-6. Alternatively, the conductive via 162 is tapered from the light-emitting element 132 toward the conductive line 124b-6.

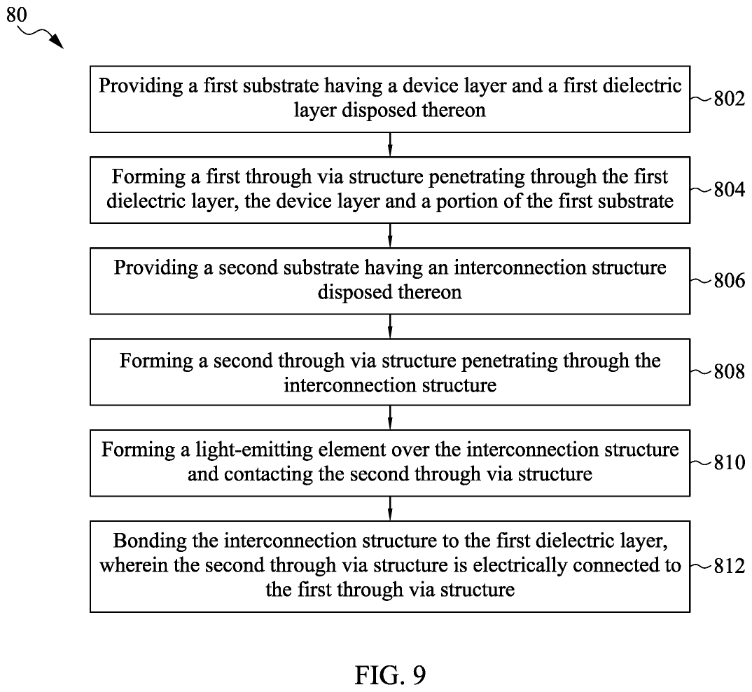

FIG. 9 is a flowchart representing a method 80 for forming a light-emitting package according to aspects of one or more embodiments of the present disclosure. The method 80 includes an operation 802, in which a first substrate having a device layer and a first dielectric layer disposed thereon is provided. The method 80 includes an operation 804, in which a first through via structure penetrating through the first dielectric layer, the device layer and a portion of the first substrate is formed. The method 80 includes an operation 806, in which a second substrate having an interconnection structure disposed thereon is provided. The method 80 includes an operation 808, in which a second through via structure penetrating through the interconnection structure is formed. The method 80 includes an operation 810, in which a light-emitting element is formed over the interconnection structure and contacts the second through via structure. The method 80 includes an operation 812, in which the interconnection structure is bonded to the first dielectric layer. The second through via structure is electrically connected to the first through via structure. The method 80 will be further described according to one or more embodiments. It should be noted that the operations of the method 80 may be rearranged or otherwise modified within the scope of the various aspects. It should further be noted that additional processes may be provided before, during, and after the method 80, and that some other processes may only be briefly described herein. Thus, other implementations are possible within the scope of the various aspects described herein.

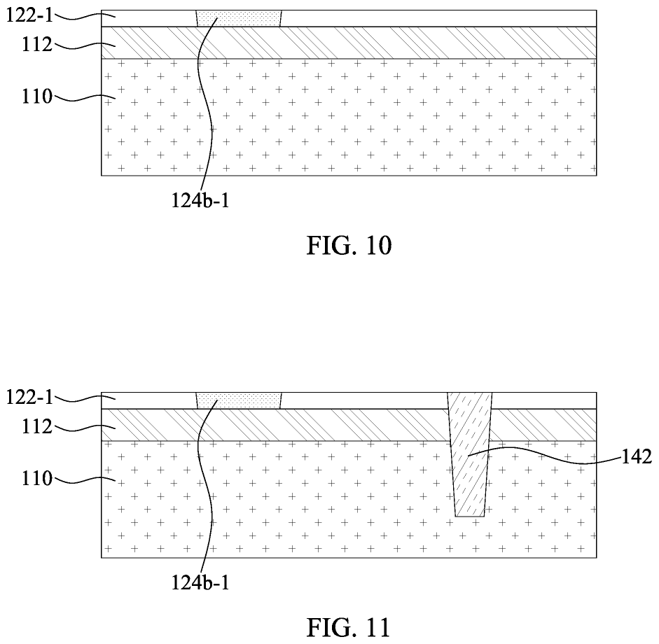

FIGS. 10 to 19 are schematic drawings illustrating a method for forming a light-emitting package at various fabrication stages constructed according to aspects of one or more embodiments of the present disclosure.

Referring to FIG. 10, a substrate 110 having a device layer 112 and a dielectric layer 122 (e.g., the IMD layer 122-1) disposed thereon is provided. The respective step is shown as the operation 802 of the method 80 in FIG. 9. The IMD layer 122-1 is formed over the substrate 110, for example, by a deposition process (such as CVD, PVD, ALD, HDPCVD, MOCVD, RPCVD, PECVD, LPCVD, ALCVD, APCVD, plating, other suitable methods, or a combination thereof). Subsequent to the deposition of the IMD layer 122-1, a chemical mechanical planarization (CMP) process and/or other planarization process is performed, such that the IMD layer 122-1 has a substantially planar surface. A conductive line 124b-1 is formed by patterning the IMD layer 122-1. Patterning the IMD layer 122-1 may include lithography processes and/or etching processes to form openings (trenches), such as line openings in the IMD layer 122-1. Thereafter, the opening(s) are filled with one or more conductive materials. The conductive material(s) can be deposited by PVD, CVD, ALD, electroplating, electroless plating, other suitable deposition process, or combinations thereof. Thereafter, any excess conductive material(s) can be removed by a planarization process, thereby planarizing a top surface of the IMD layer 122-1 and a top surface of the conductive line 124b-1.

Referring to FIG. 11, a first through via structure (e.g., the first tapered portion 142) penetrating through the IMD layer 122-1, the device layer 112 and a portion of the substrate 110 is formed. The respective step is shown as the operation 804 of the method 80 in FIG. 9. The first tapered portion 142 is formed by patterning the IMD layer 122-1, the device layer 112 and a portion of the substrate 110. Patterning the IMD layer 122-1, the device layer 112 and a portion of the substrate 110 may include lithography processes and/or etching processes to form openings (trenches), such as a through via opening in the IMD layer 122-1, the device layer 112 and a portion of the substrate 110. In some implementations, the lithography processes include forming a patterned resist layer over the IMD layer 122-1 that can be used as a masking element for etching opening(s) in the IMD layer 122-1, the device layer 112 and a portion of the substrate 110. The etching processes include dry etching processes, wet etching processes, other etching processes, or combinations thereof. Thereafter, the opening(s) are filled with one or more doped semiconductor material(s). Thereafter, any excess doped semiconductor material(s) can be removed by a planarization process, thereby planarizing a top surface of the IMD layer 122-1 and a top surface of the first tapered portion 142.

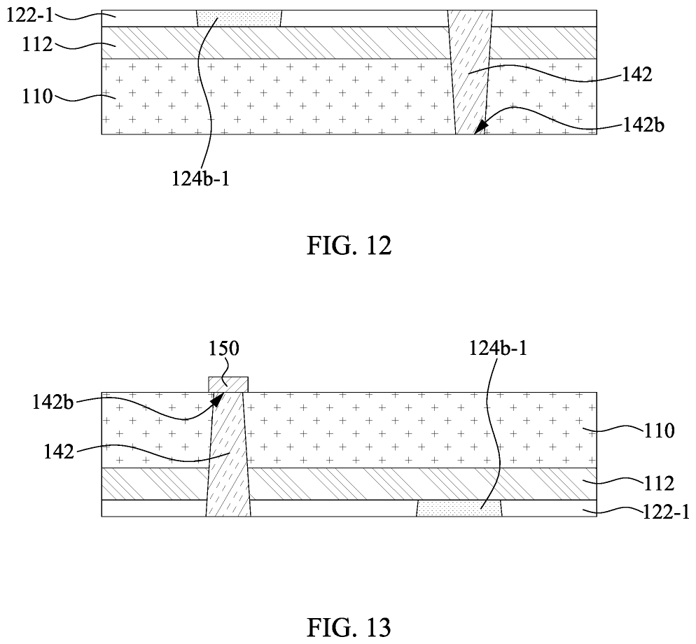

Referring to FIG. 12, a thinning operation is performed to reduce a thickness of the substrate 110 and expose an end (e.g., a surface 142b) of the first tapered portion 142. The thinning operation is applied to reduce a thickness of the substrate 110. The thinning process may include a mechanical grinding process, a chemical thinning process, or a combination thereof. For example, a substantial amount of substrate material may be first removed from the substrate 110 during the mechanical grinding process. Next, the chemical thinning process may apply an etching chemical to the back side of the substrate 110 to further thin the substrate 110 to expose the surface 142b of the first tapered portion 142.

Referring to FIG. 13, a conductive pad 150 is formed over the surface 142b of the first tapered portion 142. The formation of the conductive pad 150 may include depositing a layer of conductive materials. The conductive material(s) can be deposited by PVD, CVD, ALD, electroplating, electroless plating, other suitable deposition process, or a combination thereof. Thereafter, the conductive pad 150 is formed by patterning the layer of conductive materials. Patterning the layer of conductive materials may include lithography processes and/or etching processes.

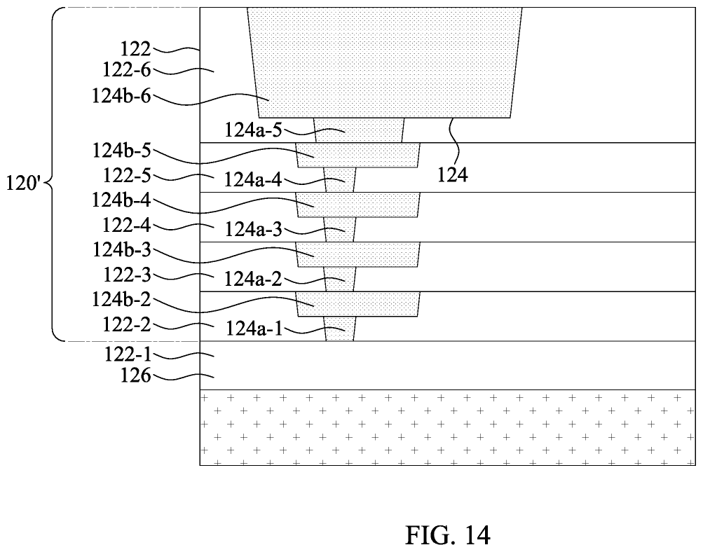

Referring to FIG. 14, a substrate 170 having an interconnection structure 120′ disposed thereon is provided. The respective step is shown as the operation 806 of the method 80 in FIG. 9. In some embodiments, the substrate 170 serves as a carrier substrate for forming the interconnection structure 120′. The substrate 170 may be made of a material same as that of the substrate 110. In some embodiments, a sacrificial dielectric layer 126 is formed between the interconnection structure 120′ and the substrate 170. The sacrificial dielectric layer 126 may be made of a material same as that of the dielectric layer 122. The dielectric layer 126 and the IMD layers 122-2 to 122-6 are formed over the substrate 170, for example, by a deposition process (such as CVD, PVD, ALD, HDPCVD, MOCVD, RPCVD, PECVD, LPCVD, ALCVD, APCVD, FCVD, plating, other suitable methods, or combinations thereof). Subsequent to the deposition of the dielectric layer 126 and the IMD layers 122-2 to 122-6, a planarization process is performed, such that the dielectric layer 126 and the IMD layers 122-2 to 122-6 have substantially planar surfaces.

The conductive vias 124a-1 to 124a-5 and conductive lines 124b-2 to 124b-6 are formed by patterning the IMD layers 122-2 to 122-6. Patterning the IMD layers 122-2 to 122-6 can include lithography processes and/or etching processes to form openings (trenches), such as via openings and/or line openings in the respective IMD layers 122-2 to 122-6. In some implementations, the lithography processes include forming a patterned resist layer over the respective IMD layers 122-2 to 122-6 that can be used as a masking element for etching opening(s) in the respective IMD layers 122-2 to 122-6. The etching processes include dry etching processes, wet etching processes, other etching processes, or combinations thereof. Thereafter, the opening(s) are filled with one or more conductive materials. The conductive material(s) can be deposited by PVD, CVD, ALD, electroplating, electroless plating, other suitable deposition process, or a combination thereof. Thereafter, any excess conductive material(s) can be removed by a planarization process, thereby planarizing a top surface of the IMD layers 122-2 to 122-6, the conductive vias 124a-1 to 124a-5, and/or the conductive lines 124b-2 to 124b-6.

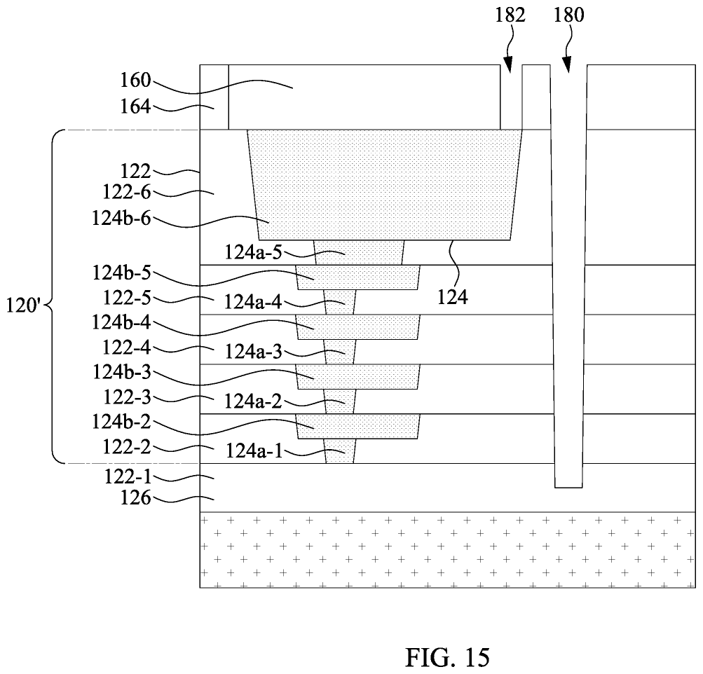

Referring to FIG. 15, a dielectric layer 164 may be optionally formed. Thereafter, an optical isolation 160 is formed by patterning the dielectric layer 164. Patterning the dielectric layer 164 can include lithography processes and/or etching processes to form openings (trenches) in the dielectric layer 164. Thereafter, the opening(s) are filled with one or more dielectric materials. The dielectric material(s) can be deposited by CVD, PVD, ALD, HDPCVD, MOCVD, RPCVD, PECVD, LPCVD, ALCVD, APCVD, plating, other suitable methods, or a combination thereof. Thereafter, any excess dielectric material(s) can be removed by a planarization process.

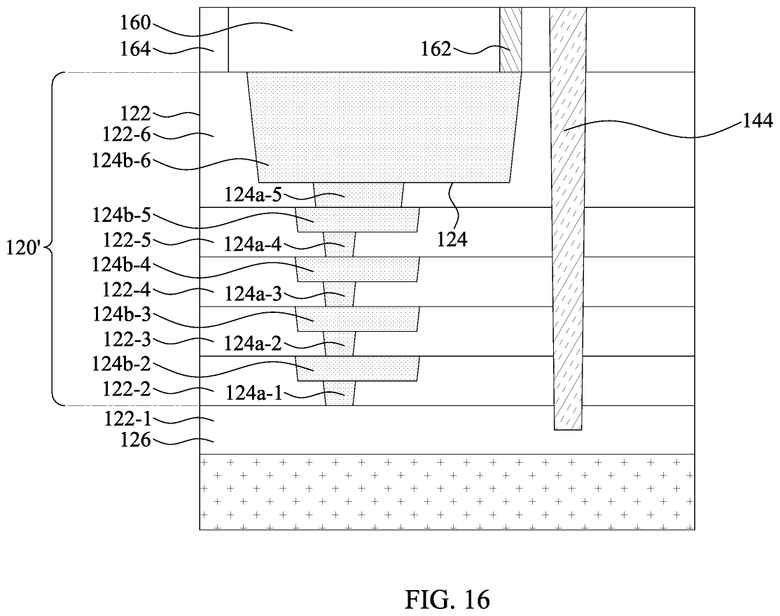

With continued reference to FIG. 15, a through via opening 180 and a via opening 182 are formed. In some embodiments, the through via opening 180 is formed by patterning the dielectric layer 164, the IMD layers 122-2 to 122-6, and a portion of the sacrificial dielectric layer 126. The via opening 182 is formed by patterning the dielectric layer 164. The through via opening 180 and the via opening 182 may be formed by different operations. For example, the via opening 182 may be formed prior to the formation of the through via opening 180. Alternatively, the through via opening 180 is formed prior to the formation of the via opening 182. Patterning the dielectric layer 164, the IMD layers 122-2 to 122-6, and the portion of the sacrificial dielectric layer 126 may include lithography processes and/or etching processes. The lithography processes include forming a patterned resist layer over the dielectric layer 164 that can be used as a masking element for etching the through via opening 180 and/or the via opening 182. The etching processes include dry etching processes, wet etching processes, other etching processes, or combinations thereof. In some embodiments, a depth of the through via opening 180 is selected such that the depth of a bottom surface of the resulting through via structure (see FIG. 16) is lower than a bottom surface of the conductive via 124a-1.

Referring to FIG. 16, a through via structure (e.g., the second tapered portion 144) penetrating through the interconnection structure 120′ is formed. The respective step is shown as the operation 808 of the method 80 in FIG. 9. In some embodiments, the through via opening 180 and/or the via opening 182 are filled with one or more doped semiconductor material(s). The doped semiconductor material(s) can be deposited by PVD, CVD, ALD, electroplating, electroless plating, other suitable deposition process, or a combination thereof. Thereafter, any excess conductive material(s) can be removed by a planarization process, thereby planarizing a top surface of the second tapered portion 144 and a top surface of the conductive via 162.

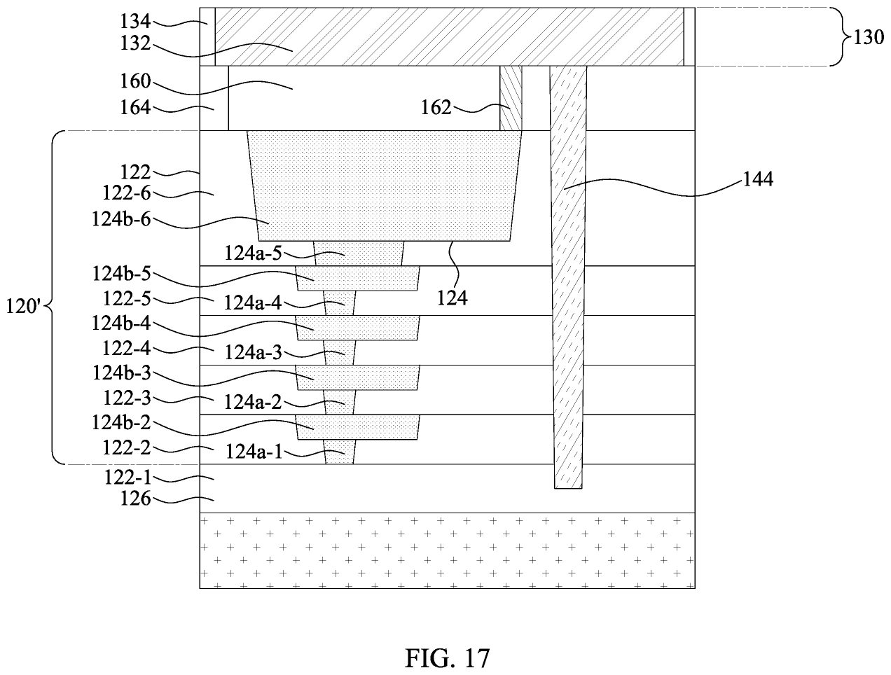

Referring to FIG. 17, a light-emitting element 132 is formed over the optical isolation 160 and contacts the second tapered portion 144. In some embodiments where the optical isolation 160 is omitted, the light-emitting element 132 is formed over the interconnection structure 120′ and contacts the second tapered portion 144. The respective step is shown as the operation 810 of the method 80 in FIG. 9. In some embodiments, the light-emitting element 132 is formed by patterning the dielectric layer 134, depositing light-emitting material(s) and removing excess light-emitting material(s) by a planarization process.

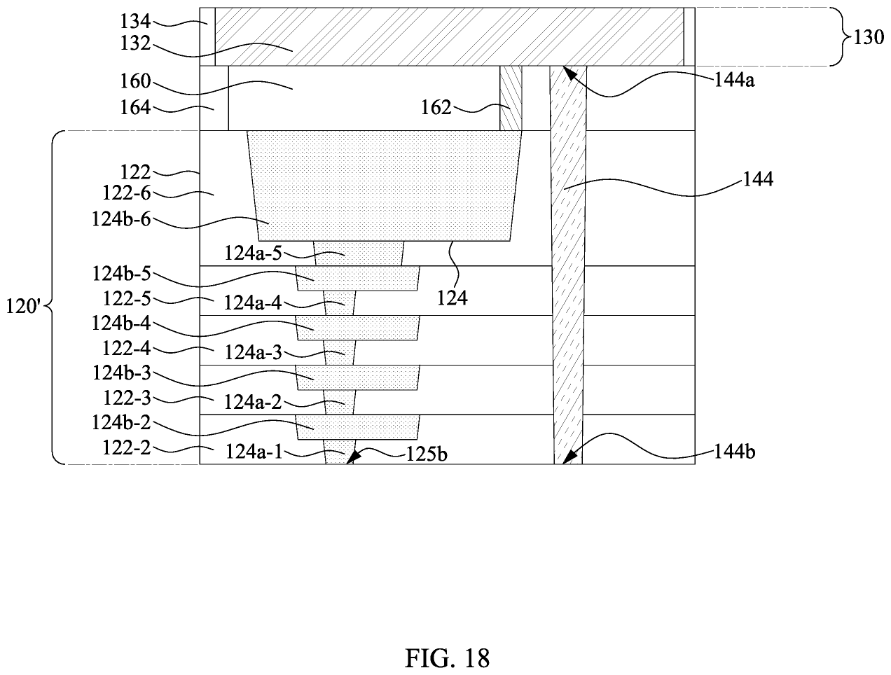

Referring to FIG. 18, a thinning operation is performed to expose an end (e.g., a surface 144b) of the second tapered portion 144 through the interconnection structure 120′. In some embodiments, the thinning operation is performed to expose an end (e.g., a surface 125b) of the conductive via 124a-1 through the interconnection structure 120′. The thinning operation is applied to reduce the thickness of the substrate 170 and the sacrificial dielectric layer 126. In some embodiments, both the substrate 170 and the sacrificial dielectric layer 126 are removed after the thinning operation. The thinning process may include a mechanical grinding process, a chemical thinning process, or a combination thereof.

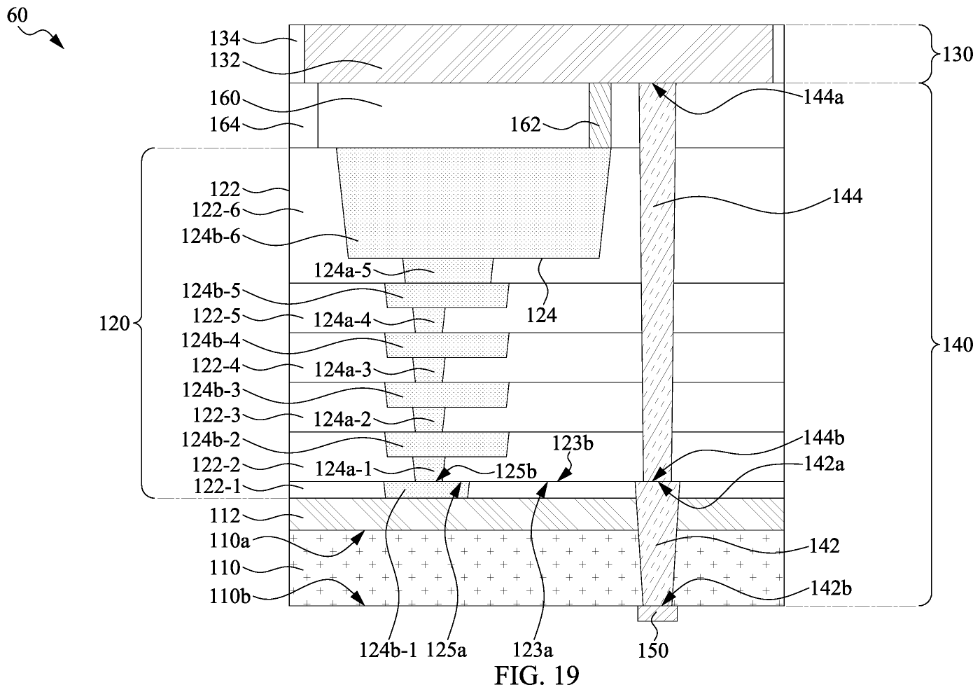

Referring to FIG. 19, the interconnection structure 120′ is bonded to the IMD layer 122-1. The respective step is shown as the operation 812 of the method 80 in FIG. 9. In some embodiments, the interconnection structure 120′ is bonded to the dielectric layer 122-1 through a hybrid bonding operation. The second tapered portion 144 is electrically connected to the first tapered portion 142. The surface 144b of the second tapered portion 144 electrically connects to and/or physically connects to the surface 142a of the first tapered portion 142. The conductive via 124a-1 is electrically connected to the conductive line 124b-1. The surface 125b of the conductive via 124a-1 electrically connects to and/or physically connects to the surface 125a of the conductive line 124b-1. Accordingly, a light-emitting package 60 is formed.

While FIGS. 10 to 19 are described with reference to some embodiments of a method, it will be appreciated that the structures shown in FIGS. 10 to 19 are not limited to the method but rather may stand alone separate of the method. While FIGS. 10 to 19 are used to illustrate a series of procedures, it will be appreciated that the order of the procedures may be altered in other embodiments. While FIGS. 10 to 19 illustrate a specific set of procedures, some procedures that are illustrated and/or described may be omitted in other embodiments. Further, procedures that are not illustrated and/or not described may be included in other embodiments.

The proposed light-emitting packages provide one or more improvements over existing approaches. The proposed light-emitting package includes one or more thermoelectric elements. The thermoelectric element may be configured to transfer the heat generated by the light-emitting element to the backside of the substrate, and hence reduce the temperature of the light-emitting package. Because the temperature of the light-emitting package is reduced, the damage to nearby components may be reduced. Accordingly, better performance of the light-emitting packages may be expected.

In accordance with some embodiments of the present disclosure, a light-emitting package is provided. The light-emitting package includes a substrate, an interconnection structure and a thermoelectric element. The interconnection structure is disposed over the substrate. The interconnection structure comprises a light-emitting element. The thermoelectric element penetrates through the substrate, extends into the interconnection structure and stops at the light-emitting element. The thermoelectric element is configured for local cooling of the light-emitting element.

In accordance with some embodiments of the present disclosure, a light-emitting package is provided. The light-emitting package includes a substrate, an interconnection structure, a light-emitting element, a conductive pad and a doped semiconductor structure. The substrate has a front surface and a back surface. The interconnection structure is disposed over the front surface of the substrate. The interconnection structure comprises a metallization layer. The light-emitting element is disposed over the interconnection structure. The light-emitting element is electrically connected to the metallization layer. The conductive pad underlies the back surface of the substrate. The conductive pad is configured to receive an input voltage. The doped semiconductor structure is adjacent to the metallization layer. The doped semiconductor structure penetrates the interconnection structure and the substrate. The doped semiconductor structure is electrically connected to the light-emitting element and the conductive pad.

In accordance with some embodiments of the present disclosure, a method for forming a light-emitting package is provided. The method includes the following operations. A first substrate having a device layer and a first dielectric layer disposed thereon is provided. A first through via structure penetrating through the first dielectric layer, the device layer and a portion of the first substrate is formed. A second substrate having an interconnection structure disposed thereon is provided. A second through via structure penetrating through the interconnection structure is formed. A light-emitting element is formed over the interconnection structure and contacts the second through via structure. The interconnection structure is bonded to the first dielectric layer. The second through via structure is electrically connected to the first through via structure.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting package, comprising:
a substrate;
an interconnection structure over the substrate, wherein the interconnection structure comprises a light-emitting element; and
a thermoelectric element penetrating through the substrate, extending into the interconnection structure and stopping at the light-emitting element, wherein the thermoelectric element is configured for local cooling of the light-emitting element.

2. The light-emitting package of claim 1, wherein the light-emitting element comprises a light-emitting diode (LED), a mini LED, a micro LED, a quantum dot or an organic LED (OLED).

3. The light-emitting package of claim 1, wherein the thermoelectric element is doped with a p-type dopant or an n-type dopant.

4. The light-emitting package of claim 3, wherein the thermoelectric element comprises a doped polysilicon.

5. The light-emitting package of claim 1, wherein the thermoelectric element is tapered from the light-emitting element toward a first surface of the substrate.

6. The light-emitting package of claim 1, wherein the thermoelectric element comprises:
a first tapered portion penetrating through the substrate; and
a second tapered portion penetrating a portion of the interconnection structure and coupled to the first tapered portion.

7. The light-emitting package of claim 6, wherein a height of the second tapered portion is greater than a height of the first tapered portion.

8. The light-emitting package of claim 6, wherein the second tapered portion has a first surface contacting the light-emitting element, and a second surface opposite to the first surface.

9. The light-emitting package of claim 8, wherein a width of the first surface is greater than a width of the second surface.

10. The light-emitting package of claim 1, further comprising:
a conductive pad underlying the substrate and electrically connected to the thermoelectric element, wherein the conductive pad is configured to receive an input voltage.

11. A light-emitting package, comprising:
a substrate having a front surface and a back surface;
an interconnection structure over the front surface of the substrate, comprising a metallization layer;
a light-emitting element over the interconnection structure, wherein the light-emitting element is electrically connected to the metallization layer;
a conductive pad underlying the back surface of the substrate, configured to receive an input voltage; and
a doped semiconductor structure adjacent to the metallization layer, penetrating the interconnection structure and the substrate, and electrically connected to the light-emitting element and the conductive pad.

12. The light-emitting package of claim 11, further comprising:
an optical isolation between the light-emitting element and the metallization layer.

13. The light-emitting package of claim 12, further comprising:
a conductive via adjacent to the optical isolation and electrically connecting the metallization layer to the light-emitting element.

14. The light-emitting package of claim 13, wherein a material of the conductive via is substantially same as a material of the doped semiconductor structure.

15. The light-emitting package of claim 13, wherein the conductive via is tapered from the light-emitting element toward the metallization layer.

16. A method for forming a light-emitting package, comprising:
providing a first substrate having a device layer and a first dielectric layer disposed thereon;
forming a first through via structure penetrating through the first dielectric layer, the device layer and a portion of the first substrate;
providing a second substrate having an interconnection structure disposed thereon;
forming a second through via structure penetrating through the interconnection structure;
forming a light-emitting element over the interconnection structure and contacting the second through via structure; and
bonding the interconnection structure to the first dielectric layer, wherein the second through via structure is electrically connected to the first through via structure.

17. The method of claim 16, wherein the second through via structure is electrically connected to the light-emitting element.

18. The method of claim 16, further comprising:
performing a first thinning operation to reduce a thickness of the first substrate and to expose an end of the first through via structure.

19. The method of claim 18, further comprising:
forming a conductive pad over the end of the first through via structure, wherein the conductive pad is configured to receive an input voltage.

20. The method of claim 16, further comprising:
performing a second thinning operation to expose an end of the second through via structure through the interconnection structure.
